(19) United States
(12) Patent Application Publication
(10) Pub. No.: US 2016/0218245 A1
(43) Pub. Date: Jul. 28, 2016

(54) TOP AND BOTTOM ELECTRODE DESIGN FOR PRINTED VERTICAL LEDS

(71) Applicant: Nthdegree Technologies Worldwide Inc., Tempe, AZ (US)

(72) Inventor: Bradley Steven Oraw, Chandler, AZ (US)

(21) Appl. No.: 14/973,683

(22) Filed: Dec. 17, 2015

Related U.S. Application Data
(60) Provisional application No. 62/108,922, filed on Jan. 28, 2015.

(51) Int. Cl. H01L 33/42; H01L 33/54; H01L 33/62

(52) U.S. Cl. CPC H01L 33/42; H01L 33/62; H01L 33/54

(57) ABSTRACT

In one example of forming a printable vertical LED that can emit light from its top and bottom surfaces, a transparent insulating material, such as silicon nitride, is formed over the bottom semiconductor layers of the LED. The insulating material is then patterned to expose portions of the conductive semiconductor layer or a transparent current spreading layer. The shape and thickness of the patterned insulating material over the bottom surface can be selected to achieve a desired orientation of the printed LED and the desired spreading of current. A thin layer of a transparent conductive material is then deposited over the surfaces of the insulating material and the exposed semiconductor surface, including the sidewalls of the openings. The top bump of the LED may be formed using the existing undoped GaN as the patterned insulating material, or an insulating layer may be deposited and patterned.

### CROSS-REFERENCE TO RELATED APPLICATIONS

This application claims the benefit of U.S. provisional application Ser. No. 62/108,922, filed Jan. 28, 2015, by Bradley S. Oraw, assigned to the present assignee and incorporated herein by reference.

### FIELD OF THE INVENTION

This invention relates to printable vertical light emitting diodes (LEDs) and, in particular, to an electrode-forming technique that improves optical and electrical performance while providing control over the orientation of the printed LEDs.

### BACKGROUND

The present assignee has developed a technique for printing microscopic vertical LEDs, as an LED ink, in a desired orientation on a thin conductive substrate. The LED ink is then cured such that the bottom electrodes of the LEDs make electrical contact to the conductive substrate. The printed LEDs are then sandwiched between the conductive substrate and a transparent conductor layer so as to be connected in parallel. The LEDs are energized by applying a forward biasing voltage between the two conductive layers. Various printing techniques and designs of the printable LEDs are described in U.S. Pat. No. 8,852,467, entitled, Method of Manufacturing a Printable Composition of Liquid or Gel Suspension of Diodes, assigned to the present assignee and incorporated herein by reference.

It is important to maximize light extracting from the LEDs.

FIG. 1A is a reproduction of a representative figure of a printable LED 10 from U.S. Pat. No. 8,852,467 to illustrate one issue with the prior art LED designs.

The LED 10 has a semiconductor p-type layer 12, a quantum well active layer 14, and an n-type layer 16. A transparent conductor layer 18, such as ITO, is deposited over the n-type layer 16 to spread current. An opaque metal bump 20 (a cathode electrode) is formed over the center area for being later contacted by another transparent conductor layer when the printed LEDs are connected in parallel. A much larger and more massive bottom die contact 22 (anode electrode) is formed to electrically contact the p-type layer 12. The shape and weight distribution of the LED causes it to orient with the die contact 22 side down. By making the bump 20 high, the LED 10 has a tendency to keep the bump 20 facing up, while the weight of the die contact 22 has a tendency to keep the die contact 22 facing down. Light is only emitted from the top surface since the die contact 22 is opaque.

In some applications, it is desirable to emit light from both the top and bottom of the LED. For example, light absorption by the semiconductor layers may be reduced by allowing the light to escape from all sides of the LED.

It is desirable to make the top opaque bump 20 smaller to increase the light emission area, but the electrical conductivity to the n-type layer 16 suffers. As described below, the bump 20 and die contact 22 cannot be formed of a transparent conductor.

There is a distinct tradeoff between transparency and conductivity of the bump and die contact features for a vertical LED. Both of these features are several micrometers in height and width. Common metals such as Ti, Al, Ni, Au are opaque at these thicknesses. Transparent conductive oxides do not solve the problem since they have high absorption at these thicknesses and at the 450 nm wavelength typical for a GaN-based LED. Hence, conventional transparent conductive materials are not suitable for the bump 20 and die contact 22.

Although many variations of a printed LED are described in U.S. Pat. No. 8,852,467, they all have the same issues described above.

What is desirable is a technique for forming the bump and/or die contact for a vertical LED, where the functions of good conductivity and selective LED orientation (after printing) are achieved while also making the bump and/or die contact transparent for improved light extraction.

### SUMMARY

In one example of forming a printable vertical LED that can emit light from its top and bottom surfaces, a transparent insulating material, such as silicon nitride, is formed over the bottom semiconductor layers of the LED. In the example, we assume the top is n-type GaN and the bottom is p-type GaN. In one embodiment, an optional transparent conductor, such as ITO, is deposited over the bottom surface of the p-type GaN to spread current prior to the insulating material being deposited. The insulating material is then patterned to expose portions of the ITO layer. The shape and thickness of the patterned insulating material over the bottom surface can be selected to achieve a desired orientation of the printed LED and the desired spreading of current.

A thin layer of a transparent conductive material is then deposited over the surfaces of the insulating material and the exposed ITO surface, including the sidewalls of the openings. Since the conductive material layer may be very thin, it may be formed of Ti, Al, Ni, Au, or other metals/alloys and be transparent. The transparent conductive material may also be a conventional transparent material such as AZO (Al-doped zinc oxide), ITO (indium tin oxide), etc. Importantly, the thickness of the transparent conductive material is virtually independent of the functions of selective orientation and electrical contact to the semiconductor layers.

The combination of the patterned insulating material and the transparent conductive material forms the die contact for the LED.

The bottom semiconductor layers are thus electrically contacted by the thin layer of transparent conductive material within the patterned openings in the insulating material, and the transparent conductive material along the sidewalls electrically connects the semiconductor layers to the transparent conductive material on the main surface of the insulating material. After printing the LED on a conductive surface of a substrate, the flat surface of the transparent conductive material then serves as the electrical contact to the conductive surface. Light may then escape from the bottom and sides of the LED to reduce light absorption by the semiconductor layers.

The top bump of the LED may be formed in a similar way or, if there is sufficient insulating semiconductor material (e.g., undoped GaN) on the n-type layer side of the LED, the GaN may be patterned to form the bump and expose the conductive n-type material, followed by depositing the conformal layer of the transparent conductive material. Light can then escape the top surface.

In one example, a relative large volume of the transparent insulating material is deposited on the intended “bottom” surface of the semiconductor layers for ensuring the LED is oriented, after printing, with its bottom surface facing the conductive substrate. A high bump also promotes this orientation. Current may be uniformly distributed to the semiconductor layers by the patterning (distribution of openings) of the insulating layer.

As seen, the bump and die contact may be transparent while having virtually any shape and thickness to achieve the desired orientation without adversely affecting electrical conductivity to the semiconductor layers and while improving light extraction.

Although the example allowed light to be emitted from both the top and bottom surfaces of the LED, the device may be formed so that light is only emitted from the top or bottom surface.

Other embodiments of the invention are described.

### BRIEF DESCRIPTION OF THE DRAWINGS

FIG. 1A is a perspective view of the assignee's own prior art printable LED design.

FIG. 1B illustrates sandwiching the printed LED of FIG. 1A, or any of the novel LEDs described herein, between two conductor layers.

FIG. 2 is a perspective view of the die contact side of a printable LED, in accordance with one embodiment of the invention.

FIG. 3 is a perspective view of the bump side of the printable LED of FIG. 2.

FIG. 4 shows the LED of FIGS. 2 and 3 as semi-transparent and the alignment of the die contact and bump.

FIG. 5 is a cross-sectional view along line 5-5 in FIG. 4.

FIG. 6 is a perspective view of the die contact side of another printable LED.

FIG. 7 is a perspective view of the bump side of the printable LED of FIG. 6.

FIG. 8 is a perspective view of the die contact side of another printable LED.

FIG. 9 is a cross-sectional view of an LED similar to that of FIGS. 6-8.

FIG. 10 is a cross-sectional view of an LED where the die contact and bump are designed so that the orientation of the LED after printing is bump side down.

FIG. 11 illustrates a general application of the invention where the transparent insulating layer (or semi-insulating layer) is a patterned semiconductor, where the insulating layer exposes a conductive semiconductor, and where a transparent conductor layer is deposited over the insulating layer and conductive semiconductor. Light is emitted through the conductive semiconductor.

FIG. 12 illustrates a general application of the invention where a patterned deposited transparent insulating layer is formed over a conductive semiconductor, and where a transparent conductor layer is deposited over the insulating layer and conductive semiconductor. Light is emitted through the conductive semiconductor.

FIG. 13 illustrates a general application of the invention where a current spreading first transparent conductor layer is deposited over a conductive semiconductor followed by forming a patterned insulating layer over the first transparent conductor, followed by depositing a second transparent conductor over the insulating layer. Light is emitted through the conductive semiconductor.

Elements that are similar or identical in the various figures are labeled with the same numeral.

### DETAILED DESCRIPTION

A novel bump (typically top electrode) and die contact (typically bottom electrode) of a vertical LED is disclosed. The structures are particularly suited for a printable LED since the orientation can be selected based on the design of the bump and die contact without adversely affecting the electrical properties. However, the invention may also provide advantages for non-printable LEDs.

Some background describing the general fabrication of the LEDs (dies) for printing is described below, followed by the novel technique of forming the bump and die contact.

In the example, the LED includes standard semiconductor GaN layers, including an n-type layer, an active layer, and a p-type layer. GaN LEDs typically emit blue light. The LEDs, however, may be any type of LED, based on other semiconductors and/or emitting red, green, yellow, or other color light, including light outside the visible spectrum, such as the ultraviolet or infrared regions.

The GaN-based micro-LEDs are less than a third the diameter of a human hair and less than a tenth as high, rendering them essentially invisible to the naked eye when the LEDs are spread across a substrate for illlumination. This attribute permits construction of a nearly or partially transparent light-generating layer made with micro-LEDs. In one embodiment, the LEDs have a diameter less than 50 microns and a height less than 20 microns. The number of micro-LED devices per unit area may be freely adjusted when applying the micro-LEDs to a substrate. The LEDs may be printed as an ink using screen printing or other forms of printing. Further detail of forming a light source by printing microscopic vertical LEDs, and controlling their orientation on a substrate, can be found in U.S. Pat. No. 8,852,467, entitled, Method of Manufacturing a Printable Composition of Liquid or Gel Suspension of Diodes, assigned to the present assignee and incorporated herein by reference.

Many thousands of vertical LEDs are completely formed on a wafer, including the bump and die contact, by using one or more carrier wafers during the processing and removing the growth substrate to gain access to both LED surfaces for forming the bump and die contact. The LED wafer is bonded to the carrier wafer using a dissolvable bonding adhesive. After the LEDs are formed on the wafer, trenches are photolithographically defined and etched in the front surface of the wafer around each LED, to a depth needed to expose the adhesive, so that each LED has a diameter of less than 50 microns and a thickness of about 2-20 microns, making them essentially invisible to the naked eye. A preferred shape of each LED is hexagonal. The bonding adhesive is then dissolved in a solution to release the LEDs from the carrier wafer. Singulation may instead be performed by thinning the back surface of the wafer until the LEDs are singulated. The microscopic LEDs are then uniformly infused in a solvent, including a viscosity-modifying polymer resin, to form an LED ink for printing, such as screen printing or flexographic printing.

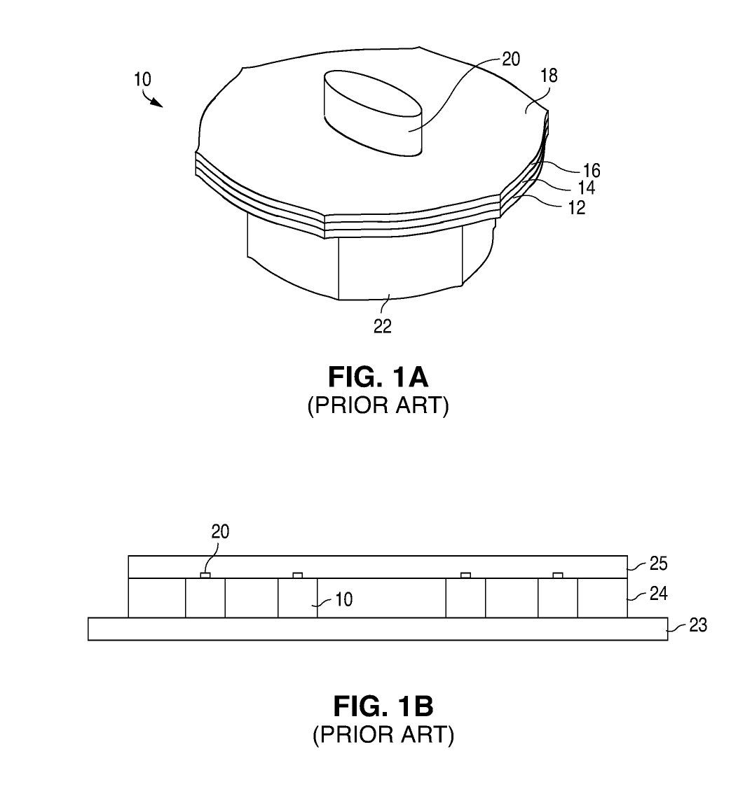

As shown in FIG. 1B, the LED ink is then printed over a conductive layer 23 on a substrate. The orientation of the LEDs can be controlled by the design of the bump and die contact, described later. The locations of the printed LEDs are random, but the approximate number of LEDs printed per unit area can be controlled by the density of LEDs in the ink. The LED ink is heated (cured) to evaporate the solvent. After curing, the LEDs remain attached to the underlying conductive 23 layer with a small amount of residual resin that was dissolved in the LED ink as a viscosity modifier. The adhesive properties of the resin and the decrease in volume of resin underneath the LEDs during curing press the bottom die contact (e.g., anode electrode) against the underlying conductive layer 23, creating a good electrical connection. Over 90% like orientation has been achieved. Alternatively, the LEDs may be designed so that half the LEDs are in one orientation and the other half are in the opposite orientation and the LEDs are powered with AC.

A transparent polymer dielectric layer 24 is then selectively printed over the conductive layer 23 to encapsulate the sides of the LEDs and further secure them in position. The ink used to form the dielectric layer 24 pulls back from the upper surface of the LEDs, or de-wets from the top of the LEDs, during curing to expose the top bumps 20 (e.g., cathode electrodes). If any dielectric remains over the LEDs, a blanket etch step may be performed to expose the top bumps 20.

To produce a lamp that emits upward and away from the substrate, a transparent conductor layer 25, such as ITO or sintered silver nano-wires forming a mesh, is then printed to contact the top bumps 20. The transparent conductor layer 25 is cured by lamps to create good electrical contact to the bumps 20.

The LEDs in the monolayer are thus connected in parallel by the two conductor layers assuming the LEDs have the same orientation. Since the LEDs are connected in parallel, the driving voltage will be approximately equal to the voltage drop of a single LED.

A phosphor layer may be printed over the LEDs for wavelength-conversion of the LED light. In one embodiment, the LEDs emit blue light and the phosphor is a YAG phosphor emitting yellow-green light so that the composite light is white. Full color displays may be formed by printing the LEDs in addressable pixel locations and using red and green phosphor dots to create red, green, and blue pixels.

The invention is directed to the formation of the bump and die contact of an LED irrespective of the application of the LED. Various examples are given.

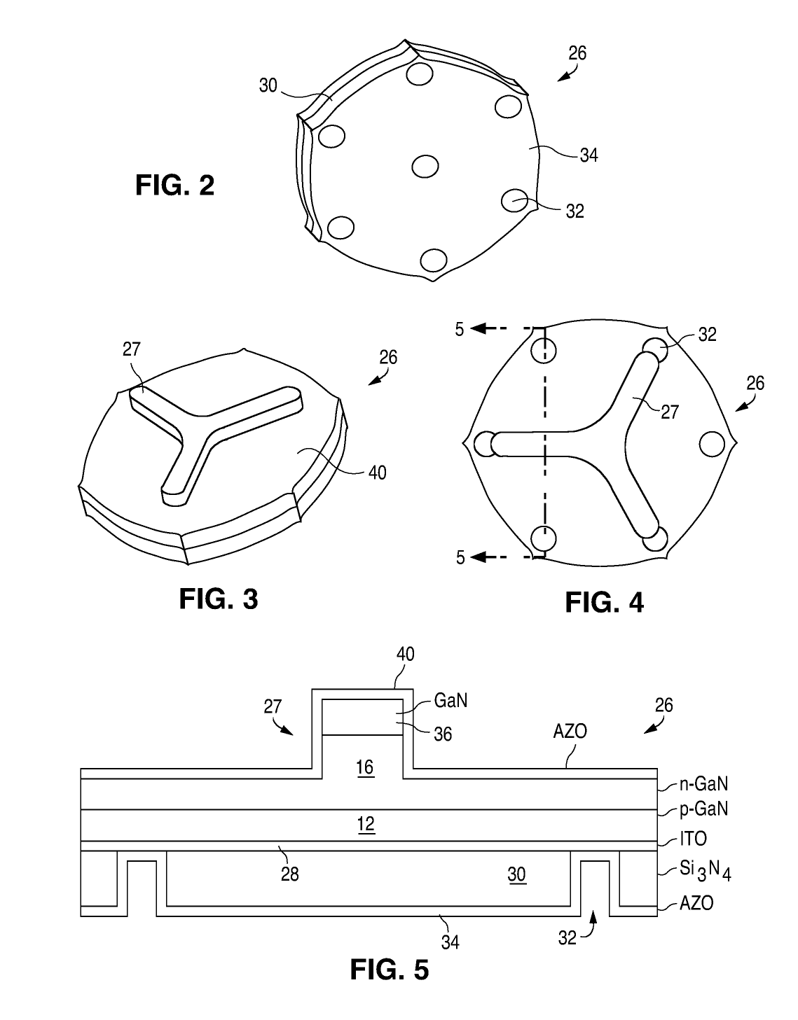

FIG. 2 illustrates the bottom surface of an LED 26, showing the die contact, in accordance with one embodiment of the invention. FIG. 3 illustrates the top surface of the LED 26, showing the bump 27. FIG. 4 shows the bump and die contact overlaid in a transparent LED 26. FIG. 5 is a cross-sectional view of the LED 26 along line 5-5 in FIG. 4.

In the example of FIG. 5, a thin transparent conductor layer 28 (FIG. 5), such as a 55 nm thick ITO layer, is first printed over the bottom p-type layer 12 to spread current. The conductor layer 28 is optional.

A transparent insulating material 30, such as 2 um thick, is then deposited over the conductor layer 28. Insulators such as PECVD-deposited Si₃N₄ or SiO₂ are suitable in most applications. These materials at several micrometers thick still have low absorption at the 450 nm wavelength.

The insulating material 30 is then patterned using a conventional photolithographic masking and etching process to form contact openings 32 that expose the transparent conductor layer 28. If the transparent conductor layer 28 was not used, the openings 32 would expose the p-type GaN layer 12.

A thin layer of another transparent conductor 34, such as a 55-220 nm AZO layer, is then deposited on the all the surfaces of the insulating material 30 and the exposed transparent conductor 28, including the opening's sidewalls, so that the bottom flat surface of the LED electrically contacts the p-type GaN layer 12. The AZO may conformally coat the surfaces by sputtering. The thickness of the transparent conductor 34 should be selected for sufficient conductance and low absorption. A thickness of 55 nm is best for low absorption in most applications. However, thicker layers such as 100 nm to 200 nm might be necessary for low lateral and vertical resistance and for continuous coverage on the insulator opening sidewall. If suitable, the transparent conductor 34 may be a metal, such as Al, Ti, Au, or Ni, if made sufficiently thin. The density of the openings 32 is determined by the desired current spreading by the conductor 34.

The index of refraction of the insulating material 30 can be selected to promote light transmission out of the semiconductor layers and out of the LED into the surrounding optical medium. For example, a GaN semiconductor has an index of refraction of 2.49. Si₃N₄ has an index of refraction close to 2.0, and, SiO₂ has an index of refraction close to 1.5. The transparent conductor 34, using ITO or AZO, has an index close to 2.0. Hence, a Si₃N₄ insulator is best to match the transparent conductor 34 index. Moreover if the surrounding medium is a polymer (e.g., forming an encapsulating lens) with an index close to 1.5, an intermediate index of 2.0 is optimal between GaN and the polymer.

The LED wafer is then reversed, using a carrier wafer, for processing the other side, shown in FIG. 3. The order of processing the LED wafer sides may be reversed, depending on the best way to minimize process steps.

Since the n-type side faces a growth substrate (e.g., sapphire) prior to the growth substrate's removal, a thick undoped GaN layer 36 is typically first epitaxially grown to provide better lattice matching of the n-type layer 16. This GaN layer 36 may serve as the patterned insulating layer to shape the bump 27, even though it may be deemed semi-insulating. This reduces processing costs since a separate insulating layer is not needed. If the GaN layer 36 is not thick enough, a Si₃N₄ layer may be deposed as previously described. The GaN layer 36 and a portion of the conductive n-type layer 16 are thinned and patterned by etching to create the desired bump shape. In the example, the bump shape is a three-arm shape to distribute current and make good electrical contact to a transparent conductor layer (shown in FIG. 1B) that is used to connected multiple printed LEDs in parallel.

A thin transparent conductor 40, such as a 55-220 nm AZO layer, is then deposited to cover the top surface of the LED and electrically contact the exposed n-type layer 16.

The bump and die contact may be aligned or not aligned.

In the example, the shape of the bump and the shape/size of the die contact cause the printed LED to be oriented with the die contact down on a conductive layer after printing. The bump and die contact are relatively thick and transparent, which could not be achieved using conventional conductive materials. Therefore, light transmission through the entire top and bottom surfaces of the LED, as well as the sides, is achieved for improved light extraction, while electrical contact to the semiconductor layers is excellent, and the shapes of the bump and die contact are freely designed to determine the orientation when printing.

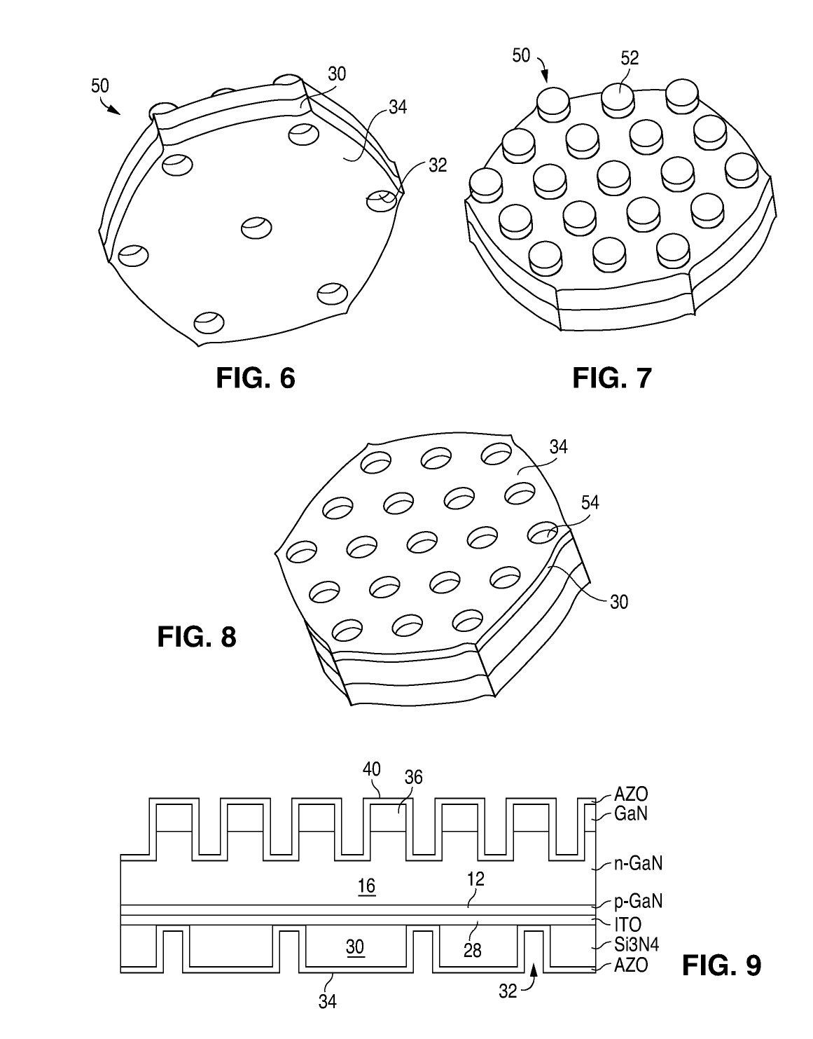

FIG. 6 shows the die contact on an LED 50 that is similar to that shown in FIG. 2. The bump side is shown in FIG. 7, where multiple bumps 52, such as 3 um pillars with a pitch of 6 um, are used to distributed current and provide good electrical contact to an overlying transparent conductor layer (shown in FIG. 1B) after the LEDs are printed on a conductive substrate.

FIG. 8 illustrates a different design of the die contact where there are more openings 54 than in FIG. 6.

FIG. 9 is a cross-sectional view representing the embodiments of FIGS. 6-8, where the cross-section bisects multiple bumps and multiple openings in the die contact. The materials are the same as in FIG. 5 except for the patterning of the insulating material 30 and GaN layer 36. The volume of the insulating material on the die contact side (insulating material 30) is greater than that on the bump side (GaN layer 36), and this relative volume along with the shape of the bumps 52 cause the LEDs to orient with the die contact down after printing.

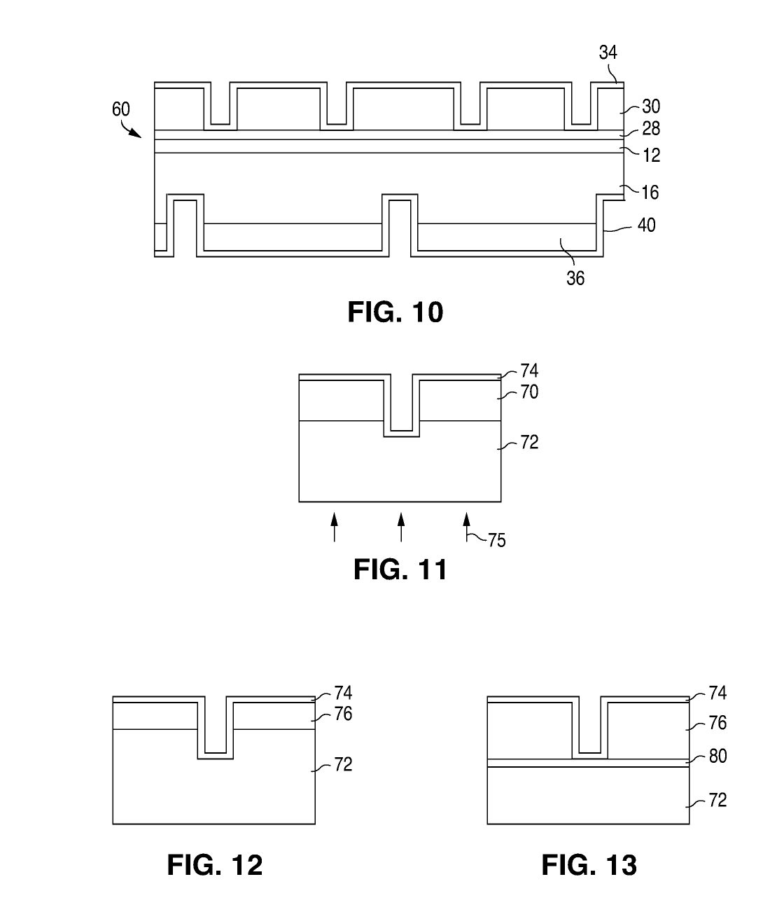

FIG. 10 is an example of an LED die 60 where there is a relatively large amount of the GaN layer 36 and n-type layer 16 remaining after etching. This added weight on the bump side causes the LED to be oriented bump side down after printing.

Although the examples described particularly pertain to forming printable LEDs that may be used in the light sheet or pixel application shown in FIG. 1B, this technique may be used for more general applications where light extraction is important while providing a relatively thick transparent insulating layer between the light generating surface and the transparent electrode surface. FIGS. 11-13 illustrate the general application of the invention.

In FIG. 11, the semiconductor material 70 may be sufficiently insulating to act as the insulating material that is patterned. The patterning exposes a more conductive semiconductor material 72, such as n-type or p-type, and the transparent conductor layer 74 conformally coats the semiconductor materials 70/72 to create an electrical connection between the top surface of the transparent conductor layer 74 and the semiconductor material 72. Light 75 is transmitted through the semiconductor materials 70/72 and the transparent conductor layer 74.

FIG. 12 illustrates an embodiment where a separate insulating material layer 76 is deposited over the conductive semiconductor material 72 and patterned along with a portion of the semiconductor material 72. The transparent conductor layer 74 directly contacts the semiconductor material 72 through the opening. Light is transmitted through the semiconductor material 72, the insulating material layer 76, and the transparent conductor layer 74.

FIG. 13 is similar to FIG. 5, where the conductive semiconductor layer 72 is electrically contacted via a separate transparent conductor layer 80 to spread current. The transparent conductor layers 74 and 80 may be different materials or the same and may be different thicknesses. Light is transmitted through the semiconductor material 72, the transparent conductor layer 80, the insulating material layer 76, and the transparent conductor layer 74.

In FIGS. 11-13, the patterned openings may be distributed along the entire surface of the conductive semiconductor material 72 to more uniformly distribute current.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A light emitting device comprising:
a first semiconductor layer of a first conductivity type;
a second semiconductor layer of a second conductivity type, where light is emitted at an interface of the first semiconductor layer and the second semiconductor layer;
a transparent first insulating layer overlying the first semiconductor layer, the first insulating layer being patterned to have one or more first openings with sidewalls; and
a first transparent conductor layer deposited over the first insulating layer to at least partially cover a surface of the first insulating layer, the sidewalls, and bottoms of the one or more first openings, the first transparent conductor layer forming a first electrode of the light emitting device for bonding to a first conductive surface for electrically contacting the first semiconductor layer.

2. The device of claim 1 wherein the light emitting device is a printable device, using an ink, and the first insulating layer is designed to achieve a desired orientation of the device after printing.

3. The device of claim 1 wherein the device is a light emitting diode (LED) die, wherein the first semiconductor layer is a p-type layer and the second semiconductor layer is an n-type layer, wherein the first insulating layer is an epitaxially grown semiconductor layer overlying the second semiconductor layer.

4. The device of claim 1 wherein the insulating layer is a deposited layer.

5. The device of claim 1 further comprising a second transparent conductor layer formed over the first semiconductor layer, wherein the first insulating layer is formed and patterned over the second transparent conductor layer to expose areas of the second transparent conductor layer.

6. The device of claim 1 wherein the first insulating layer is a deposited layer, the device further comprising:
a transparent second insulating layer overlying the second semiconductor layer, the second insulating layer being patterned to have one or more second openings with sidewalls; and
a second transparent conductor layer deposited over the second insulating layer to at least partially cover a surface of the second insulating layer, the sidewalls of the one or more second openings, and bottoms of the one or more second openings, the second transparent conductor layer forming a second electrode of the light emitting device for bonding to a second conductive surface for electrically contacting the second semiconductor layer.

7. The device of claim 6 wherein the second insulating layer is an epitaxially grown semiconductor layer overlying the second semiconductor layer.

8. The device of claim 1 wherein the one or more first openings comprises one opening.

9. The device of claim 1 wherein the one or more first openings comprises a plurality of openings.

10. The device of claim 1 wherein the light emitting device is a printable device, using an ink, and the first insulating layer is designed to cause the first semiconductor layer to be oriented downward after printing.

11. The device of claim 1 wherein the light emitting device is a printable device, using an ink, and the first insulating layer is designed to cause the first semiconductor layer to be oriented upward after printing.

12. The device of claim 1 further comprising a transparent second electrode electrically contacting the second semiconductor layer, wherein light exits the light emitting device at least through the second electrode.

13. The device of claim 13 wherein the second electrode is formed as one or more bumps on a surface of the light emitting device opposite to the first electrode.

14. The device of claim 1 further comprising the first conductive surface, wherein the first transparent conductor layer is bonded to the first conductive surface.

15. The device of claim 14 further comprising a second conductive surface opposing the first conductive surface, wherein the second semiconductor layer is electrically connected to the second conductive surface.

16. The device of claim 15 wherein the light emitting device is printed, using an ink, and cured to bond the first transparent conductor layer to the first conductive surface.
